(19) United States
(12) Patent Application Publication
(10) Pub. No.: US 2015/0299845 A1
(43) Pub. Date: Oct. 22, 2015

(54) FILM AND METHOD FOR PREPARING THE SAME

(71) Applicants: SHENZHEN BYD AUTO R&D COMPANY LIMITED, Shenzhen, Guangdond (CN); BYD COMPANY LIMITED, Shenzhen, Guangdong (CN)

(72) Inventors: WEI ZHOU, Shenzhen (CN); YONGLIANG SUN, Shenzhen (CN)

(21) Appl. No.: 14/440,676

(22) PCT Filed: Dec. 11, 2013
(86) PCT No.: PCT/CN2013/008912

§ 371 Date: May 5, 2015

(30) Foreign Application Priority Data
Dec. 21, 2012 (CN) 201210559311.2

(51) Int. Cl. C23C 14/35; C23C 14/12; C03C 17/00; G02B 1/18; C23C 14/02; C23C 14/06; G02B 1/111; G02B 1/14; C23C 14/00; C23C 14/54

(52) U.S. Cl. CPC C23C 14/35; C23C 14/0057; C23C 14/12; C03C 17/009; C23C 14/54; C23C 14/021; C23C 14/0694; C23C 14/022; G02B 1/111; G02B 1/14; G02B 1/18; C03C 2218/156

(57) ABSTRACT

A film and a method for preparing the film are provided. A substrate is provided, and a film is formed on at least a part of a surface of the substrate by magnetron sputtering a target under a protective gas and a reactive gas. The target includes polytetrafluoroethylene and magnesium fluoride, and the reactive gas includes at least one selected from a group consisting of CF₄ and SiF₄.

### CROSS REFERENCE TO RELATED APPLICATION

This application claims priority and benefits of Chinese Patent Application No. 201210559311.2, filed with the State Intellectual Property Office, P. R. C. on Dec. 21, 2012, the entire content of which is incorporated herein by reference.

### TECHNICAL FIELD

The present disclosure relates to the field of film fabrication and, especially, relates to a film and a method for preparing the film.

### BACKGROUND

With the development of electronic industry, touch screens are used more and more widely, for example, in mobile phones, MP3 devices, computers, ATMs, medical facilities, industrial control equipment, displays and TVs. However, fingerprints and oil stains formed on the touch screen during repeated usage of the touch screens are so difficult to remove that it prevents the touch screens from operating normally.

In addition, when a device having the touch screen (such as a cell phone) is used under the sunlight, the touch screen will reflect the sunlight and data displayed on the touch screen may be unclear, which makes it difficult to read or edit a message, or to dial numbers. Some users try to solve this problem by increasing the brightness of the touch screen. Unfortunately, the effect is poor. Moreover, it reduces the normal service time of the battery of the cell phone.

### SUMMARY

Embodiments of the present disclosure seek to solve at least one of the existing problems in the prior art to at least some extent, or to provide a useful commercial choice.

Embodiments of a first broad aspect of the present disclosure provide a method for preparing a film. The method may include: providing a substrate, and forming a film on at least a part of a surface of the substrate by magnetron sputtering a target under a protective gas and a reactive gas. The target includes polytetrafluoroethylene and magnesium fluoride, and the reactive gas includes at least one selected from a group consisting of CF4 or SiF4.

With the method according to embodiments of the present disclosure, a film including polytetrafluoroethylene doped with magnesium fluoride and having low surface energy and low refractive index may be formed on a surface of a touch screen by magnetron sputtering (for example, using the touch screen as the substrate). The method may be simple to operate and low in cost. The film prepared according to embodiments of the present disclosure may have low surface energy, thus a surface of the film may have a larger oil contact angle and lower adhesive property. Therefore, a touch screen covered by the film may be difficult to be stained with fingerprints or oils, and may be easy to clean. In addition, the film may have a rather low refractive index that a reflecting rate of the touch screen covered with the film may be reduced from about 10% to lower than about 1%. In this way, data displayed on the touch screen may be clearly read even under strong sunlight. In addition, the film prepared according to embodiments of the present disclosure may have better wear resistance.

Embodiments of a second broad aspect of the present disclosure provide a film prepared by the method mentioned above.

The film according to embodiments of the present disclosure may include polytetrafluoroethylene doped with magnesium fluoride and have a low surface energy and a low refractive index. The film may be formed on a surface of a touch screen by magnetron sputtering, for example, using the method mentioned above and using the touch screen directly as the substrate. A surface of the film may have a larger oil contact angle and low adhesive property. Therefore, a touch screen covered by the film may be difficult to be stained with fingerprints or oils, and may be easy to clean. In addition, the film may have a rather low refractive index that a reflecting rate of the touch screen covered with the film may be reduced from about 10% to about 1%. In that way, data displayed on the touch screen may be clearly read even under strong sunlight. Further, the film prepared according to embodiments of the present disclosure may have better wear resistance.

Additional aspects and advantages of embodiments of present disclosure will be given in part in the following descriptions, become apparent in part from the following descriptions, or be learned from the practice of the embodiments of the present disclosure.

### DETAILED DESCRIPTION

Reference will be made in detail to embodiments of the present disclosure. The embodiments described herein are explanatory, illustrative, and used to generally understand the present disclosure. The embodiments shall not be construed to limit the present disclosure.

In the specification, relative terms such as “first” and “second” are used herein for purposes of description and are not intended to indicate or imply relative importance or significance.

Before any embodiments of the disclosure are explained in detail, it should be understood that the disclosure is not limited in its application to the details of construction and the arrangement of components set forth in the following description or illustrated in the following drawings. The disclosure is capable of other embodiments and of being practiced or of being carried out in various ways. Also, it should be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

Embodiments of the present disclosure provide a method for preparing a film. The method includes the steps of: providing a substrate, and forming a film on at least a part of a surface of the substrate by magnetron sputtering a target under a protective gas and a reactive gas, in which the target includes polytetrafluoroethylene and magnesium fluoride, and the reactive gas includes at least one selected from a group consisting of CF4 and SiF4.

With the method according to embodiments of the present disclosure, a film including polytetrafluoroethylene doped with magnesium fluoride and having low surface energy and low refractive index may be formed on a surface of a touch screen by magnetron sputtering (for example, using the touch screen as the substrate). The method may be simple to operate and low in cost. The film prepared according to embodiments of the present disclosure has a low surface energy, thus a surface of the film may have a larger oil contact angle and a lower adhesive property. Therefore, a touch screen covered by the film may be difficult to be stained with fingerprints or oils, and may be easy to clean. In addition, the film may have a rather low refractive index that a reflecting rate of the touch screen covered with the film may be reduced from about 10% to lower than about 1%. In that way, data displayed on the touch screen may be clearly read even under strong sunlight. In addition, the film prepared according to embodiments of the present disclosure may have better wear resistance.

As will be readily understood by those skilled in the art, atoms or molecules of the reactive gas may be deposited on the surface of the substrate together with atoms of the target, thus forming the film on the substrate. By using CF4 and SiF4 as the reactive gas, fluorine (F) content in the film may be increased, therefore providing the film with better performances, such as better wear resistance or the like.

In some embodiments, a mole ratio of polytetrafluoroethylene to magnesium fluoride may be in a range of about 1:(0.05-1). In some other embodiments, a mole ratio of polytetrafluoroethylene to magnesium fluoride is in a range of about 1:(0.1-0.5). Then the properties of the film obtained may be further improved.

In some embodiments, the target may be formed by the following steps: mixing particles of polytetrafluoroethylene and magnesium fluoride to form a first mixture; mixing the first mixture with oil to form a second mixture; and sintering the second mixture. In one embodiment, the steps of forming the target may further include curing the second mixture prior to sintering the second mixture. In another embodiment, the step of forming the target may further include molding the second mixture after sintering the second mixture. This way, the properties of the film obtained may be further improved.

Those with ordinary skill in the art will appreciate that any suitable methods of mixing with oil, curing and sintering may be applied, which are known in the art. In some embodiments, mixing the first mixture with oil may be carried out by evenly mixing the first mixture with graphite (about 5wt %). In one embodiment, curing the second mixture may be carried out by resting the second mixture at a temperature of about 250 Celsius degree for about 30 minutes. In one embodiment, sintering the second mixture may be carried out at a temperature of about 330 Celsius degree to about 380 Celsius degree for about 30 minutes. This way, the properties of the film obtained may be further improved.

In some embodiments, the protective gas may include at least one selected from a group consisting of N2 and inert gas. It is well known by those skilled in the art that the inert gas includes the gas corresponding to elements in Group VIIIA of the periodic table of elements. Thus, the properties of the film obtained may be further improved.

In one embodiment, a volume-flow ratio of the protective gas to the reactive gas is in a range of about 1:(0.1-1), such that the properties of the film obtained may be further improved.

In some embodiments of the present disclosure, a purity of the protective gas and a purity of the reactive gas may be both greater than about 99.99%. With the reactive gas having this high purity, introducing impurities into the obtained film from the reactive gas may be efficiently avoided.

In some embodiments, a volume flow of the protective gas may be about 200 sccm to about 500 sccm, a volume flow of the protective gas may be greater than 0 sccm and less than about 200 sccm. This way, the properties of the film obtained may be further improved.

In some embodiments of the present disclosure, the magnetron sputtering may be performed by any suitable magnetron sputtering method known to those skilled in the art. In one embodiment, the magnetron sputtering may be radio frequency magnetron sputtering using a conventional magnetron sputtering device, for example, a magnetron sputtering coater (JP-900A, commercially available from Beijing Beiyi Innovation Vacuum Technology Co. LTD., P.R.C.) using a radio-frequency (RF) power of about 13.56 MHz, 3 KW as the working power. This way, the properties of the film obtained may be further improved.

In some embodiments, the magnetron sputtering may be performed for about 5 minutes to about 25 minutes under the condition of: a pressure of about 0.3 Pa to about 2 Pa, a bias voltage of about 50 V to about 500 V, a duty ratio of about 15% to about 90% and a sputtering power of about 300 W to about 3000 W. Then the properties of the film obtained may be further improved.

Alternatively, the magnetron sputtering may be performed for about 8 min to about 15 min under a condition of: a pressure of about 0.5 Pa to about 1 Pa, a bias voltage of about 50 V to about 250 V, a duty ratio of about 40% to about 60% and a sputtering power of about 900 W to about 1500 W. Under such condition, the properties of the film obtained may be further improved.

In some embodiments, the pressure of about 0.3 Pa to about 2 Pa may be formed by the steps of: reducing a pressure of a vacuum chamber to lower than about 5.0×10-3 Pa by vacuumizing the vacuum chamber, and increasing the pressure of the vacuum chamber to about 0.3 Pa to about 2 Pa by feeding the reactive gas and the protective gas into the vacuum chamber. This way, the properties of the film obtained may be further improved.

Specifically, in one embodiment of the present disclosure, the magnetron sputtering may be performed by a magnetron sputtering coater having a vacuum chamber, and the magnetron sputtering may include the following operation steps: the vacuum chamber is vacuumized until the pressure in the vacuum chamber is lower than 5.0×10-3 Pa; the reactive gas and the protective gas are fed into the vacuum chamber until the pressure reaches a range of 0.3 Pa to 2 Pa; the bias voltage is regulated to a range of 50 V to 500 V and the duty ratio is regulated to a range of 10% to 90%; and finally sputtering is performed for 5 minutes to 25 minutes with a sputtering power of 300 W to 3000 W. This way, the properties of the film obtained may be further improved.

In one embodiment, the method further includes a step of cleaning the substrate by ultrasonic cleaning prior to the magnetron sputtering. The cleaning step may be performed by any suitable ultrasonic cleaning method known by those skilled in the art. For example, the substrate may be cleaned in water under an ultrasonic wave having a frequency of about 20 KHz for about 10 minutes to about 25 minutes. With the step of cleaning, the obtained film may have a better light transmittance and a better adhesion force with the substrate (for example, the touch screen). Thus, the properties of the film obtained may be further improved.

In some embodiments, the method further comprises a step of treating the substrate by ionic bombardment prior to the magnetron sputtering. By using the ionic bombardment, a surface activity of the substrate may be increased, and the adhesion force between the film and the substrate may be improved. Thus, the properties of the film obtained may be further improved.

Any suitable ionic bombardment method may be applied in the present disclosure, such as, ionic bombardment using argon, i.e., argon ion bombardment.

In one embodiment, the ion bombardment may be performed with argon and for about 5 minutes to about 20 minutes under the condition of: a pressure of about 0.1 Pa to about 5 Pa, a bias voltage of about 200 V to about 1000 V and a duty ratio of about 20% to about 70%. Under such condition, the properties of the film obtained may be further improved.

Alternatively, the ion bombardment may be performed with argon and for about 8 minutes to about 15 minutes under the condition of: a pressure of about 0.5 Pa to about 3.0 Pa, a bias voltage of about 400 V to about 800 V and a duty ratio of about 35% to about 55%. Under such condition, the properties of the film obtained may be further improved.

In some embodiments, the pressure of about 0.1 Pa to about 5 Pa may be formed by the steps of: reducing a pressure of a vacuum chamber to about 1.0×10-2 Pa to about 8.0×10-2 Pa by vacuumizing the vacuum chamber, and increasing the pressure of the vacuum chamber to about 0.1 Pa to about 5 Pa by feeding argon into the vacuum chamber. This way, the properties of the film obtained may be further improved.

Specifically, in one embodiment of the present disclosure, the substrate may be treated by the ion bombardment in a vacuum chamber, and the ion bombardment may include the following operation steps: 1) the vacuum chamber is vacuumized until the pressure in the vacuum chamber reaches about 1.0×10-2 Pa to about 8.0×10-2 Pa; argon are fed into the vacuum chamber until the pressure of the vacuum chamber reaches a range of 0.1 Pa to about 5 Pa; the substrate is subjected to ion bombardment for 5 minutes to about 20 minutes under a bias voltage of about 200 V to about 1000 V and a duty ratio of about 20% to about 70%. This way, the properties of the film obtained may be further improved.

According to another embodiment of the present disclosure, a film is provided. The film is prepared by the method mentioned above.

The film according to embodiments of the present disclosure may have a low reflective index, a better wear resistance, a better corrosion resistance, and a better adhesion with the substrate. The film may be formed on a surface of a touch screen by magnetron sputtering, for example, using the method mentioned above and taking the touch screen as the substrate. A surface of the film may have a larger oil contact angle and a lower adhesive property. Therefore, the touch screen covered by the film may be difficult to be stained with fingerprints or oils, and may be easy to clean. In addition, the film may have a rather low refractive index that a reflecting rate of the touch screen covered with the film may be reduced from about 10% to about 1%. In that way, data displayed on the touch screen may be clearly read even under strong sunlight. For the benefits of the film indicated above, the film according to embodiments of the present disclosure may also be referred as an “anti-fingerprint film” or “anti-reelection film”.

In some embodiments, the film may have a thickness of about 10 nanometers to about 30 nanometers. Alternatively, the film may have a thickness of about 15 nanometers to about 30 nanometers.

The present disclosure will be described below in detail with reference to the following examples.

### EXAMPLE 1

Polytetrafluoroethylene particles and magnesium fluoride particles (the mole ratio of polytetrafluoroethylene to magnesium fluoride was 1:0.1) were mixed evenly to form a first mixture. Then the first mixture was mixed with oil to form a second mixture, and the second mixture was cured, sintered and molded in turn to form a target A1.

A glass substrate was cleaned in an ultrasonic instrument for 20 minutes under a frequency of 20 KHz, and then placed in a vacuum chamber of a magnetron sputtering apparatus. The vacuum chamber was vacuumized until a pressure in the vacuum chamber reached 1.0×10-2 Pa. Then argon was fed into the vacuum chamber until the pressure of the vacuum chamber reached 1.5 Pa. Then the glass substrate was subjected to an ion bombardment for 8 minutes under a bias voltage of 600 volts and a duty ratio of 50%.

The target A1 was placed in the vacuum chamber. The vacuum chamber was vacuumized until the pressure in the vacuum chamber reached 5.0×10-3 Pa. And then, argon and CF4 gas having a volume ratio of 1:0.5 were fed into the vacuum chamber, with a volume flow of argon being 400 sccm and a volume flow of CF4 being 200 sccm, until the pressure in the vacuum chamber reached 1.0 Pa. Then the target was sputtered using RF magnetron sputtering for 10 minutes and under a condition of: a sputtering power of 1000 W, a bias voltage of 200 volts and a duty ratio of 50%, to form a film B1 on the surface of the glass substrate.

Finally, the glass substrate formed with the film B1 was cooled for 3 minutes, obtaining a sample B10.

### EXAMPLE 2

Polytetrafluoroethylene particles and magnesium fluoride particles (the mole ratio of polytetrafluoroethylene to magnesium fluoride was 1:0.5) were mixed evenly to form a first mixture. Then the first mixture was mixed with oil to form a second mixture, and the second mixture was cured, sintered and molded in turn to form a target A2.

A glass substrate was cleaned in an ultrasonic instrument for 20 minutes under a frequency of 20 KHz, and then placed in a vacuum chamber of a magnetron sputtering apparatus. The vacuum chamber was vacuumized until a pressure in the vacuum chamber reached 1.2×10-2 Pa. Then argon was fed into the vacuum chamber until the pressure of the vacuum chamber reached 1.5 Pa. Then the glass substrate was subjected to an ion bombardment for 8 minutes under a bias voltage of 600 volts and a duty ratio of 50%.

The target A2 was placed in the vacuum chamber. The vacuum chamber was vacuumized until the pressure in the vacuum chamber reached 4.5×10-3 Pa. And then, argon and SiF4 gas having a volume ratio of 1:0.8 were fed into the vacuum chamber, with a volume flow of argon being 333 sccm and a volume flow of SiF4 being 267 sccm, until the pressure in the vacuum chamber reached 1.0 Pa. Then the target was sputtered using RF magnetron sputtering for 15 min and under a condition of: a sputtering power of 2000 W, a bias voltage of 300 volts and a duty ratio of 50%, to form a film B2 on the surface of the glass substrate.

Finally, the glass substrate formed with the film B2 was cooled for 3 minutes, obtaining a sample B20.

### EXAMPLE 3

Polytetrafluoroethylene particles and magnesium fluoride particles (the mole ratio of polytetrafluoroethylene to magnesium fluoride was 1:0.05) were mixed evenly to form a first mixture. Then the first mixture was mixed with oil to form a second mixture, and the second mixture was cured, sintered and molded in turn to form a target A3.

A glass substrate was cleaned in an ultrasonic instrument for 20 minutes under a frequency of 20 KHz, and then placed in a vacuum chamber of a magnetron sputtering apparatus. The vacuum chamber was vacuumized until a pressure in the vacuum chamber reached 1.2×10-2 Pa. Then argon was fed into the vacuum chamber until the pressure of the vacuum chamber reached 1.5 Pa. Then the glass substrate was subjected to an ion bombardment for 8 minutes under a bias voltage of 600 volts and a duty ratio of 50%.

The target A3 was placed in the vacuum chamber. The vacuum chamber was vacuumized until the pressure in the vacuum chamber reached 5.0×10-3 Pa. And then, argon and CF4 gas having a volume ratio of 1:1 were fed into the vacuum chamber, with a volume flow of argon being 300 sccm and a volume flow of CF4 being 300 sccm, until the pressure in the vacuum chamber reached 1.0 Pa. Then the target was sputtered using RF magnetron sputtering for 10 min and under a condition of: a sputtering power of 1000 W, a bias voltage of 200 volts and a duty ratio of 50%, to form a film B3 on the surface of the glass substrate.

Finally, the glass substrate formed with the film B3 was cooled for 3 minutes, obtaining a sample B30.

### EXAMPLE 4

Polytetrafluoroethylene particles and magnesium fluoride particles (the mole ratio of polytetrafluoroethylene to magnesium fluoride was 1:1) were mixed evenly to form a first mixture. Then the first mixture was mixed with oil to form a second mixture, and the second mixture was cured, sintered and molded in turn to form a target A4.

A glass substrate was cleaned in an ultrasonic instrument for 20 minutes under a frequency of 20 KHz, and then placed in a vacuum chamber of a magnetron sputtering apparatus. The vacuum chamber was vacuumized until a pressure in the vacuum chamber reached 1.2×10-2 Pa. Then argon was fed into the vacuum chamber until the pressure of the vacuum chamber reached 1.5 Pa. Then the glass substrate was subjected to an ion bombardment for 8 minutes under a bias voltage of 600 volts and a duty ratio of 50%.

The target A4 was placed in the vacuum chamber. The vacuum chamber was vacuumized until the pressure in the vacuum chamber reached 5.0×10-3 Pa. And then, argon and CF4 gas having a volume ratio of 1:0.1 were fed into the vacuum chamber, with a volume flow of argon being 550 sccm and a volume flow of SiF4 being 55 sccm, until the pressure in the vacuum chamber reached 1.0 Pa. Then the target was sputtered using RF magnetron sputtering for 10 minutes and under a condition of: a sputtering power of 1000 W, a bias voltage of 200 volts and a duty ratio of 50%, to form a film B4 on the surface of the glass substrate.

Finally, the glass substrate formed with the film B4 was cooled for 3 minutes, obtaining a sample B40.

### COMPARATIVE EXAMPLE 1

A sample DB10 (a substrate with a film DB1 formed thereon) was produced by a method substantially the same as that in Example 1, with the exception that:

using polytetrafluoroethylene particles instead of polytetrafluoroethylene particles and magnesium fluoride particles to form the target.

### COMPARATIVE EXAMPLE 2

A silica membrane having a thickness of 10 nanometers, an aluminum oxide membrane having a thickness of 10 nanometers, a zirconium dioxide membrane having a thickness of 10 nanometers, a magnesium fluoride membrane having a thickness of 10 nanometers and a polytetrafluoroethylene membrane having a thickness of 10 nanometers were formed on a surface of a glass substrate in sequence via vacuum deposition, thus obtaining a sample DB20 having a film DB2 (consisting of the membranes mentioned above) formed thereon.

Tests

The Sample B10-B40, DB10 and DB20 were tested as follows.

Reflectivity

The samples B10-B40 and DB10-DB20 were tested by using a LCD-5200 photoelectrometer, and the scanned waveband was 380-780 nm. The reflectivities of the samples B10-B40 and DB10-DB20 were calculated according to GBT 2680-1994 standard.

Contact Angle

The contact angle were tested by a contact angle meter (OCA20, commercially available from Dataphysics, German, the contact angle measuring range is 0-180 degrees and the measurement accuracy is ±0.1 degrees), using hexadecane as the testing sample. The contact angle was immediately recorded after a drop of the testing sample fell onto the surface of the samples B10-B40 and DB10-DB20.

Wear Resistance

These samples B10-B40 and DB10-DB20 were tested using a wear resistance tester (HD-206) under the condition of: a contact surface of 0000# steel wool, a contact area of 2 cm×2 cm, a load of 500 grams, a travel distance of 35 millimeters, a friction velocity of 50 cycle/min. The contact angle was tested again after the wear resistance test was performed for 1000 times.

The tested results are shown in Table 1.

TABLE 1

| | Reflectivity | Contact angle | Contact angle after wear |
|---|---|---|---|
| Sample | (%) | (degree) | resistance test (degree) |
| B10 | 2.5 | 56.4 | 55.2 |
| B20 | 1.4 | 52.8 | 51.3 |
| B30 | 5.5 | 65.4 | 62.1 |
| B40 | 0.7 | 55.2 | 54.8 |
| DB10 | 10.8 | 55.8 | 53.2 |
| DB20 | 12.5 | 54.2 | 42.3 |

As indicated in Table 1, the films according to embodiments of the present disclosure have rather large contact angles. Those with ordinary skill in the art will appreciate that, the film having large contact angle according to embodiments of the present disclosure may be good in preventing the film from being stained by fingerprints or oils, the film may further have a good wear resistance and a low refractive index.

Reference throughout this specification to “an embodiment,” “some embodiments,” or “one embodiment,” means that a particular feature, structure, material, or characteristic described in connection with the embodiment or example is included in at least one embodiment or example of the present disclosure. Thus, the appearances of the phrases such as “in some embodiments,” “in one embodiment,” or “in an embodiment,” in various places throughout this specification are not necessarily referring to the same embodiment or example of the present disclosure. Furthermore, the particular features, structures, materials, or characteristics may be combined in any suitable manner in one or more embodiments or examples.

Although explanatory embodiments have been shown and described, it would be appreciated by those skilled in the art that the above embodiments cannot be construed to limit the present disclosure, and changes, alternatives, and modifications can be made in the embodiments without departing from spirit, principles and scope of the present disclosure.

1. A method for preparing a film, comprising:
providing a substrate; and
forming a film on at least a part of a surface of the substrate by magnetron sputtering a target under a protective gas and a reactive gas,
wherein the target includes polytetrafluoroethylene and magnesium fluoride, and the reactive gas includes at least one selected from a group consisting of CF₄ and SiF₄.

2. The method according to claim 1, wherein a mole ratio of polytetrafluoroethylene to magnesium fluoride is in a range of about 1:(0.05-1).

3. The method according to claim 2, wherein the mole ratio of polytetrafluoroethylene to magnesium fluoride is further in a range of about 1:(0.1-0.5).

4. The method according to claim 1, wherein the target is formed by the following steps:
mixing particles of polytetrafluoroethylene and magnesium fluoride to form a first mixture;
mixing the first mixture with oil to form a second mixture; and
sintering the second mixture.

5. The method according to claim 4, wherein the protective gas includes at least one selected from a group consisting of N₂ and an inert gas.

6. The method according to claim 5, wherein a volume-flow ratio of the protective gas to the reactive gas is in a range of about 1:(0.1-1).

7. The method according to claim 5, wherein a volume flow of the protective gas is about 200 to about 500 sccm, and a volume flow of the protective gas is greater than 0 and less than about 200 sccm.

8. The method according to claim 1, wherein the magnetron sputtering is performed for about 5 min to about 25 min under a condition of:
a pressure of about 0.3 Pa to about 2 Pa,
a bias voltage of about 50 V to about 500 V,
a duty ratio of about 15% to about 90%, and
a sputtering power of about 300 W to about 3000 W.

9. The method according to claim 8, wherein the pressure of about 0.3 Pa to about 2 Pa is formed by the steps of:
reducing a pressure of a vacuum chamber to lower than about 5.0×10⁻³ Pa by vacuumizing, and
increasing the pressure of the vacuum chamber to about 0.3 Pa to about 2 Pa by feeding the reactive gas and the protective gas into the vacuum chamber.

10. The method according to claim 1, further comprising a step of:
cleaning the substrate by ultrasonic cleaning prior to the magnetron sputtering.

11. The method according to claim 10, further comprising a step of:
treating the substrate by ionic bombardment prior to the magnetron sputtering.

12. The method according to claim 11, wherein the ionic bombardment is performed with argon for about 5 minutes to about 20 minutes under a condition of:
a pressure of about 0.1 Pa to about 5 Pa,
a bias voltage of about 200 V to about 1000 V; and
a duty ratio of about 20% to about 70%.

13. The method according to claims 12, wherein the pressure of about 0.1 Pa to about 5 Pa is formed by the steps of:
reducing a pressure of a vacuum chamber to about 1.0×10⁻² Pa to about 8.0×10⁻² Pa by vacuumizing the vacuum chamber; and
increasing the pressure of the vacuum chamber to about 0.1 Pa to about 5 Pa by feeding argon into the vacuum chamber.

14. (canceled)

15. (canceled)

16. A device, comprising:
a substrate; and
a film formed on at least a part of a surface of the substrate,
wherein the film is formed by magnetron sputtering a target under a protective gas and a reactive gas, and the target includes polytetrafluoroethylene and magnesium fluoride, and the reactive gas includes at least one selected from a group consisting of CF₄ and SiF₄.

17. The device according to claim 16, wherein the target is formed by the following steps:
mixing particles of polytetrafluoroethylene and magnesium fluoride to form a first mixture;
mixing the first mixture with oil to form a second mixture; and
sintering the second mixture.

18. The device according to claim 16, wherein the mole ratio of polytetrafluoroethylene to magnesium fluoride is further in a range of about 1:(0.1-0.5).

19. The device according to claim 16, wherein:
the protective gas includes at least one selected from a group consisting of N₂ and an inert gas; and
a volume-flow ratio of the protective gas to the reactive gas is in a range of about 1:(0.1-1).

20. The device according to claim 16, wherein the film has a thickness of about 10 nanometers to about 30 nanometers.

21. The device according to claim 20, wherein the substrate is a touch screen.
